(19) United States
(12) Patent Application Publication
(10) Pub. No.: US 2008/0246621 A1
(43) Pub. Date: Oct. 9, 2008

(54) Leak Control System

(76) Inventor: Huaben Wu, Taishan City (CN)

Correspondence Address: CHAN LAW GROUP LC, 1055 W. 7TH ST,, SUITE 1880, LOS ANGELES, CA, 90017, US

(21) Appl. No.: 11/733,099

(22) Filed: Apr. 9, 2007

(51) Int. Cl. G08B 21/20; G01R 27/08

(52) U.S. Cl. 340/605; 324/694

(57) ABSTRACT

A leak detection system includes a first water container, a water detection probe disposed in close proximity to the first water container, the probe having a sensing circuit for generating electrical signals when moisture is sensed by the probe, a water input conduit coupled with the first water container for supplying the first water container with water from an external water source, and a water shut-off controller electronically coupled with the detection probe for regulating the supply of water from the eternal source to the first water container in response to the signals generated by the sensing circuit of the probe. The system further includes an electronic shut-off valve, and the electronic controller includes a trigger circuit for converting signals from said probe to signals for operating the shut-off valve. The water detection probe includes a first circuit having conductor means for detecting moisture-inducing electrical resistance changes, and a second circuit for converting said changes into signals for the trigger circuit. The leak detection system may also include a second container for substantially isolating the first water container and the detection probe therewithin. Preferably, the second container comprises a flexible bag having releasable closure means. The shut-off controller is electrically coupled with one or more of a light, an alarm or a buzzer, for alerting a user that a leak has been detected. The shut-off valve is caused to be closed in response to signals generated by said electronic controller. Preferably, the electronic controller includes first circuit means for determining if the strength of the signals from the water detection probe exceed a predetermined value, and second circuit means for generating a water shut-off signal that causes the shut-off valve to be closed.

### FIELD OF THE INVENTION

The present invention relates to a system for detecting leakage of fluid in fluid conveying and storage apparatus and more particularly to initiating, regulating, and terminating, the flow of fluid through fluid conveying apparatus and into a fluid reservoir when leakage of the fluid is detected either from the reservoir or from the fluid conduits conveying the fluid to and from the reservoir.

Even more particularly, the invention is directed to a completely sealed and moisture-proofed, electronically operated, water leak detection system especially useful with any water based system, such as a water purifier, a hot water heater, etc. The system of the invention includes a water container, enclosure or reservoir, an electronic water shut off controller functionally connected with an inflow conduit attached to the water container for regulating and providing or shutting off water flow to the container, and a detection probe disposed in the vicinity of the bottom of the water container and functionally coupled with the electronic controller. The electronic controller preferably includes a circuit board that is encased in a sealing material so that the board is completely sealed from the potentially moisture-laden environment in which the leak detection system is disposed.

### BACKGROUND OF THE INVENTION

There are many known types of apparatus for guarding against damage from water-containing vessels associated with utilitarian devices such as water purifiers, hot water tanks and hot water heaters, etc. Apparatus of this nature most relevant to the present invention is typified by the leak detecting mechanisms disclosed in U.S. Pat. No. 5,686,893 to Jeon and U.S. Pat. No. 4,998,096 to Benvenuti.

The leak detecting mechanism of Jeon ('893) includes an array of filter devices (27, 29, 31) secured to one side of a water storage tank 35, where the filter devices are interconnected by appropriate flexible conduits. The filter devices are disposed atop a tray 61 affixed to the same side of the storage tank. A water sensor 56 is located the below the tank in the tray that supplies a signal to a control mechanism which shuts off the water flow through the purifier when a leak is detected, displays a visual indication, and sounds an audible alarm. This patent fails to teach detection of leakage from the tank, an event which is impossible because the detector is disposed on the tray which is positioned laterally of the tank.

The patent to Benvenuti ('096) discloses a leak detection apparatus for a hot water heater or tank in which a conventional smoke alarm unit 10 is activated when a leak is detected in the vicinity of the tank. This patent teaches the use of a two wire conductor pair connected to a moisture detecting element at one end and the smoke detector at the other end. One embodiment of the patent (FIG. 5) teaches enclosing the water tank 40 in an isolating bag 60, and placing the leak detecting probe in the bag outside of the tank, preferably near the inside bottom of the bag. This patent also does not teach the present invention because there is no control mechanism for cutting off the flow of water to the tank in the event of detection of water leaking from the tank.

Neither of these patents alone, or in combination, teach the basic concept of the present invention, namely a completely electronic leak detection system having a moisture detector in close proximity to the water tank for determining whether a water tank is leaking, and being capable, upon detecting such a leaks of turning off supply of water to the tank using an electronic controller coupled to the detector.

### SUMMARY OF THE INVENTION

The present invention therefore provides a novel solution for controlling water flow to and from a water storage reservoir or container upon the detection of leakage, and does so automatically. Accordingly, one aspect of the present invention is to provide an electronic system for automatically regulating flow of water into and out of a water storage container using a moisture detector positioned in close proximity to the container that is electronically coupled with a water flow controller.

Another aspect of the present invention is to provide a leak detection system for use in proximity with a water storage reservoir or container in which a signal from a leak detection device upon detecting a predetermined quantity of moisture, will communicate with an electronic controller functionally coupled to a shut-off valve for selectively shutting off the flow of water to the reservoir or container when a leak is detected.

Still another aspect of the present invention is to provide a leak detection apparatus for various types of water storage equipment which sounds an alarm and illuminates a light when a leak or a predetermined quantity of moisture is detected.

Yet another aspect of the invention is to provide a leak detection apparatus, optionally including a water storage container, that can be completely contained and isolated in a sealed enclosure and in which a leak detection device is positioned in proximity to the storage container between the exterior of the container and the interior surface of the sealed enclosure.

Still another aspect of the invention is to provide a leak detection apparatus having an internal component make-up that increases the reliability, convenience, and efficiency of the apparatus as compared with other similar leak detection apparati. In particular, the elements of which the present invention is comprised enable isolating water- or moisture-sensitive equipment, such as computers, electrical appliances, food storage containment, etc from leaked water or moisture, or from high humidity environments.

Still another aspect of the invention is to be able to sense, in the near proximity of moisture-sensitive equipment, concentrations of moisture that exceed predetermined thresholds, and to alert users of the equipment of such excessiveness audibly, as for example by an alarm or buzzer, as well as visually, as for example by a light.

Yet another aspect of the invention is the flexibility of the installation of the detection probe, which may be placed at the bottom of an enclosure for the equipment, or in any area located in proximity to the equipment.

### BRIEF DESCRIPTION OF THE DRAWINGS

FIG. 1 is a schematic drawing showing the structural layout of a leak detection system according to the present invention;

FIG. 2 is a schematic drawing showing the electrical system used by the present invention; and

FIG. 3 is a circuit diagram for the leak detection apparatus of the invention.

### DETAILED DESCRIPTION OF THE INVENTION

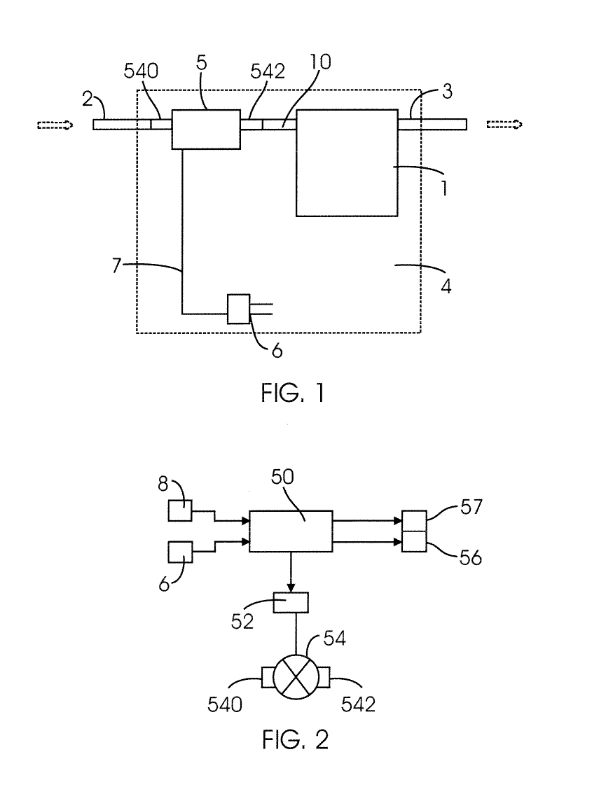

Referring first to FIG. 1, the leak detection system of the present invention is seen to include a moisture detection probe 6 located in an area 4 surrounding a water-containing enclosure 1, such as a water filter, a water heater, a dishwasher, or the like. Additionally, moisture-sensitive equipment (not shown) such as electronic equipment or computers may be installed and in use in proximity to the water containing enclosure 1. The probe 6 is electrically coupled, via a conductor 7, to an electronic controller 5. The electronic controller functions to regulate and control the flow of water to the enclosure 1 through a water inflow conduit 2 and from the enclosure 1 through a water outflow conduit 3. The electronic controller 5 is also electrically coupled to the enclosure 1) such that the water flow to the enclosure 1 can be shut off in response to an electric signal generated by the detection probe 6.

The probe 6 is comprised of a circuit have a set of wires, the electrical resistance of which changes when the probe contacts sufficient moisture to cause the circuit current to be altered, thus generating a signal. This signal is fed to the controller 5 which then can determine, based on a preset threshold parameter whether or not to shut off the supply of water to the water storage container 1.

The controller 5, which is shown schematically in FIG. 2, functions to regulate and control the initiation and termination of water flow into the enclosure 1. As shown, the controller includes a primary control circuit board 50 which is electrically coupled with an electronically actuated shut-off valve 54, and may optionally include an electronic switching trigger circuit 52. The shut-off valve 54 uses an electro-pulse valve.

The primary control board 50 is wired, via conductor 7, to the detection probe 6 located in the surrounding proximity 4, and is also electrically connected to the shut-off valve 54. The shut-off valve 54 is provided with two terminal connections, one coupled to the water supply line 540 and the other coupled to the output water line 542. Connected to the primary circuit board 50 is circuit 56 for controlling a light (not shown) and circuit 57 for controlling an alarm (not shown) for warning the user of the moisture-sensitive equipment that a leak has occurred and that the water shut-off valve 54 has been actuated to turn off the supply of water. The circuit board of the electronic controller preferably is encased in a sealing material so that the board is completely sealed from the potentially moisture-laden environment in which the leak detection system is disposed.

When the leak detection system is used, it is typically installed directly next to or in close proximity to the water enclosure 1 such that any moisture leaking or otherwise escaping from the enclosure 1 can easily be detected. The detection probe 6 is then installed in the vicinity of the moisture-sensitive equipment.

During use of the leak detection apparatus, if a leak occurs, the probe will detect the increased moisture, actuate the alarms (light and audible alarm), and cause the shut-off valve to close down the flow of water to the enclosure 1.

Optionally, the area 4 can comprise a second structural enclosure surrounding among other things the water-containing enclosure 1, the controller 5 and the detection probe 6. In this situation, when water or moisture collects inside the second enclosure 4, and reaches a predetermined level, it is detected by the detection probe 6 and a change in the electrical resistance sensed by the probe occurs generating a signal which is transmitted to the controller 5. The signal is amplified by the controller and transmitted to the circuit board 50 which causes the light and the alarm to be activated simultaneously with activation of the shut-off valve 54, thereby turning off the inflow of water to the water enclosure 1.

A power source is enclosed within the controller and preferably comprises one or more batteries packaged together. Such a “battery pack” enables the portability of the leak control system, and facilitates deployment of the system in the field. In the alternative, the controller could be outfitted with an AC or DC connector for connection to an appropriately configured external power source.

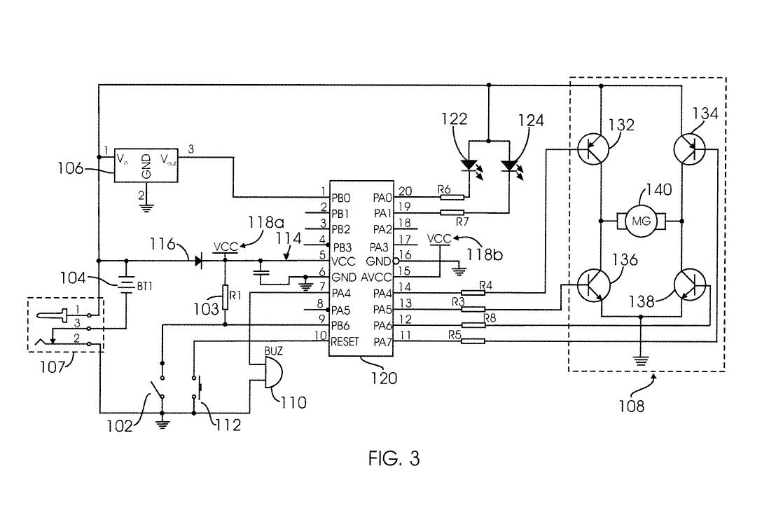

FIG. 3 is a logic circuit diagram for the leak control apparatus of the present invention, which includes a detector circuit 102 coupled to the CPU 120 on the one hand and to the battery circuit 104 on the other hand, a low voltage detector 106 coupled between the battery circuit 104 and the CPU 120, and a valve actuating circuit 108. An alarm 110 and a reset circuit 112 are connected to the CPU, as are a noise filter 114, a voltage decreasing diode 116, voltage control components 118a and 118b, and two LEDs 122, 124. The valve actuating or trigger circuit 108 includes four diodes 132, 134, 136 and 138, as well as the shut-off valve 140.

In operations when the detection probe 6 contacts moisture an electrical signal of a certain strength is generated by the detection circuit 102, and when the strength exceeds a predetermined level (a function in part of the resistance at 103), the detector circuit is actuated and the signal is passed on to the CPU 120. When the low voltage detector 106 determines that low voltage is present, a signal is sent to the CPU which in turn acts to initiate closure of valve 140, and activate the alarm mechanism 110. Resetting of the alarm mechanism and the shut-off valve 140 is accomplished via a reset mechanism (for example a push button) 112.

Those skilled in the art will appreciate that various adoptions and modifications of the invention as described above can be configured without departing from the scope and spirit of the invention. Therefore, it is to be understood that, within the scope of the appended claims, the invention may be practiced other than as specifically described herein.

What we claim is:

1. A leak detection system, comprising:
a first water container,
a water detection probe disposed in close proximity to the first water container, said probe having a sensing circuit for generating an electrical signal when moisture is sensed by the probe,
a water input conduit coupled with the first water container for supplying the first water container with water from an external water source, and
a water shut-off controller, functionally coupled with said water input conduit and electronically coupled with the detection probe, for regulating the supply of water from the external source to the first water container in response to electrical signals generated by the sensing circuit of the probe.

2. The leak detection system of claim 1, wherein said electronic controller includes a trigger circuit for converting signals from said probe to signals for operating said shut-off valve.

3. The leak detection system of claim 1, wherein said water detection probe includes a first circuit having conductor means for detecting moisture-inducing electrical resistance changes, and a second circuit for converting said changes into signals for said trigger circuit.

4. The leak detection system of claim 1, and further including a second water container comprising means for substantially isolating said first water container and said detection probe therewithin.

5. The leak detection system of claim 4, wherein said second water container comprises a flexible bag having releasable closure means.

6. The leak detection system of claim 1, wherein said water shut-off controller is electrically coupled with a light for alerting a user that a leak has been detected.

7. The leak detection system of claim 1, wherein said controller is electrically coupled with an alarm for alerting a user that a leak has been detected.

8. The leak detection system of claim 1, and further including an electronic shut-off valve functionally coupled with the electronic controller, wherein said shut-off valve is caused to be closed in response to signals generated by said electronic controller.

9. The leak detection system of claim 1, wherein said electronic controller includes first circuit means for determining if the strength of the signals from the water detection probe exceed a predetermined value, and second circuit means for generating a water shut-off signal that causes the shut-off valve to be closed.

10. The leak detection system of claim 1, wherein said water shut-off controller includes a circuit board, said circuit board being completely encased in a sealing material so that the board is isolated from any moisture-laden environment in which the leak detection system is disposed.

11. The leak detection system of claim 1, wherein said water shut-off controller includes a power supply.

12. The leak detection system of claim 11, wherein said power supply comprises one or more batteries packaged together.

13. The leak detection system of claim 11, wherein said water shut-off controller also includes one of an AC or DC connector for connection to an appropriately configured external power source.
